(19) United States
(12) Patent Application Publication
(10) Pub. No.: US 2016/0312365 A1
(43) Pub. Date: Oct. 27, 2016

(54) ELECTROLESS PLATING METHOD AND ELECTROLESS PLATING FILM

(71) Applicant: KANTO GAKUIN SCHOOL CORPORATION, Yokohama-shi (JP)

(72) Inventors: Christopher CORDONIER, Yokohama-shi (JP); Hideo HONMA, Yokohama-shi (JP)

(73) Assignee: KANTO GAKUIN SCHOOL CORPORATION, Yokohama-shi (JP)

(21) Appl. No.: 14/876,047

(22) Filed: Oct. 6, 2015

Related U.S. Application Data
(60) Provisional application No. 62/152,261, filed on Apr. 24, 2015.

(51) Int. Cl. C23C 18/16; C23C 18/18; C23C 18/34; C23C 18/44; C23C 18/54; G03F 7/16; G03F 7/36; G03F 7/40; B32B 15/01; C23C 18/40; C23C 18/31

(52) U.S. Cl. CPC C23C 18/1608; C23C 18/405; C23C 18/1844; C23C 18/1612; C23C 18/34; C23C 18/44; C23C 18/31; G03F 7/16; G03F 7/36; G03F 7/40; B32B 15/01; B32B 15/018; C23C 18/54

(57) ABSTRACT

An electroless plating method of an embodiment includes: a step of preparing a catalyst solution containing titanium alkoxide, a copper ion, a naphthoquinonediazide esterification product, and methoxyethoxyacetic acid; a step of coating a substrate with the catalyst solution; a step of patterning the coating film; a step of converting the coating film to a catalyst precursor film; a step of immersing the catalyst precursor film in a reducing agent-containing aqueous solution to reduce the copper ion to metal; and a step of forming an electroless copper plating film.

### CROSS REFERENCE TO RELATED APPLICATION

This application is based upon and claims priority from U.S. Provisional application 62/152,261 filed on Apr. 24, 2015.

### BACKGROUND OF THE INVENTION

1. Field of the Invention

The present invention relates to an electroless plating method of performing electroless plating after forming a catalyst film on a substrate and an electroless plating film formed by the electroless plating method.

2. Description of the Related Art

In electroless plating, a catalyst is applied to a non-conducting substrate, and then a film is formed by a plating method.

The adhesiveness of the electroless plating film largely depends on the adhesive strength between the catalyst and the substrate. Therefore, generally, the catalyst is applied after roughening the surface of the substrate by a chemical etching process, a physical etching process, or the like.

Japanese Patent Application Laid-Open Publication No. 9-59778 discloses a method of metalizing a ceramic using a composite film of titanium oxide and zinc oxide as a base film. The composite film is produced from a sol-gel solution made of a titanium alkoxide solution and a zinc solution. Then, the zinc oxide is selectively removed from the composite film by etching, and then electroless plating is performed after being immersed in a palladium chloride solution. The base film made of titanium oxide is excellent in adhesiveness with a substrate. Further, the base film in which a large number of pores are formed by the dissolution of zinc oxide is excellent in adhesiveness with a plating film.

Further, Japanese Patent Application Laid-Open Publication No. 9-59778 discloses formation of a catalyst film by coating a substrate with a dispersion in which titanium oxide particles carrying metal Pd particulates as a catalyst are dispersed in an organic binder.

In order to produce a patterned electroless plating film, for example, a plating film is formed on the whole surface of a substrate before an etching process is performed through an etching mask after formation of the etching mask.

Note that, in Japanese Patent Application Laid-Open Publication No. 2011-207693, the inventors disclose a method of directly producing a patterned electroless plating film by coating a substrate with a photosensitive catalyst complex film, patterning the catalyst film by subjecting the catalyst film to pattern-wise exposure, and forming an electroless plating film thereon.

### SUMMARY OF THE INVENTION

An electroless plating method of an embodiment of the present invention includes: a solution preparation step of preparing a catalyst solution containing titanium alkoxide, a copper ion, a derivative of o-benzenediol in which a substituent is introduced into a carbon atom of a 4-position of the o-benzenediol, a naphthoquinonediazide esterification product, methoxyethoxyacetic acid, and a silane coupling agent; a coating step of coating a substrate with the catalyst solution to form a coating film; a patterning step of patterning the coating film by a photolithography method; a curing step of converting the coating film to a catalyst precursor film, wherein the titanium alkoxide of the coating film is thermally decomposed to titanium oxide; a reduction step of immersing the catalyst precursor film in a reducing agent-containing aqueous solution to reduce the copper ion to metal copper; and a plating step of forming an electroless copper plating film.

### BRIEF DESCRIPTION OF THE DRAWINGS

FIG. 1 is a flowchart of an electroless plating method of a first embodiment;

FIG. 2A is a sectional view for describing the electroless plating method of the first embodiment;

FIG. 2B is a sectional view for describing the electroless plating method of the first embodiment;

FIG. 2C is a sectional view for describing the electroless plating method of the first embodiment;

FIG. 2D is a sectional view for describing the electroless plating method of the first embodiment;

FIG. 2E is a sectional view for describing the electroless plating method of the first embodiment;

FIG. 2F is a sectional view for describing the electroless plating method of the first embodiment; and

FIG. 3 is a flowchart of the electroless plating method of a second embodiment.

### DETAILED DESCRIPTION OF THE PREFERRED EMBODIMENTS

### First Embodiment

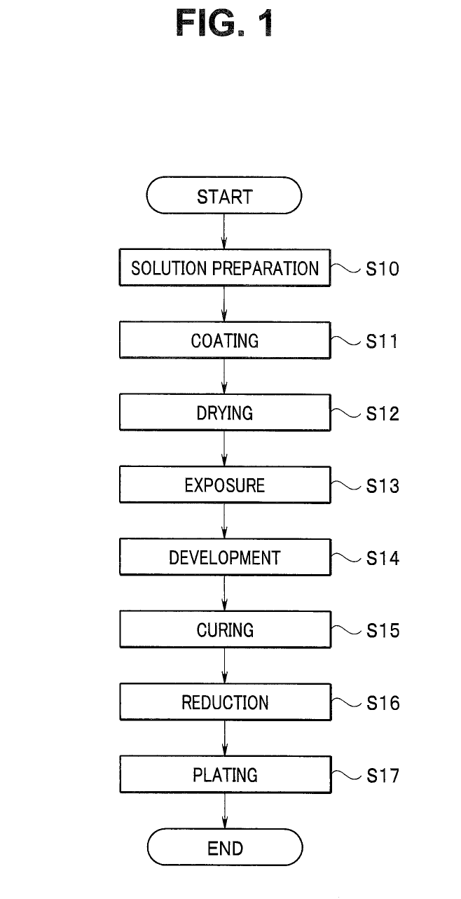

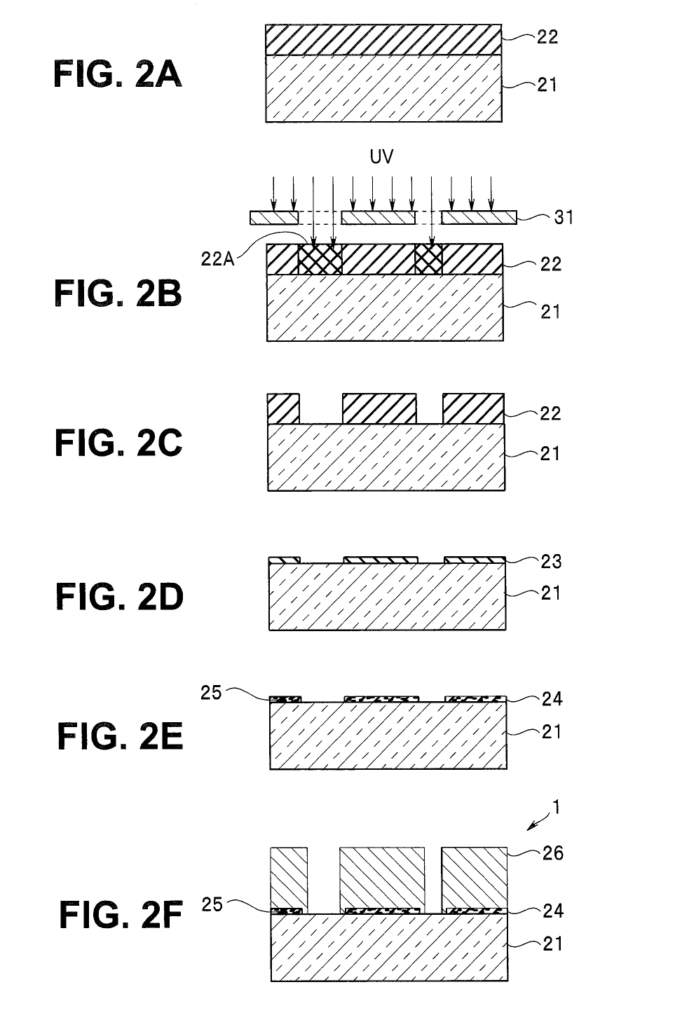

Hereinafter, an electroless plating method and an electroless plating film 26 of a first embodiment will be described using FIG. 1 and FIG. 2A to FIG. 2F.

As shown in FIG. 1, the electroless plating method of the present embodiment includes: a solution preparation step (S10) of preparing a catalyst solution; a coating step (S11) of forming a photosensitive coating film 22 on a substrate 21; a drying step (S12) of drying the coating film 22; a patterning step (S13, S14) of patterning the coating film 22; a curing step (S15) of converting the coating film 22 to a catalyst precursor film 23; a reduction step (S16) of converting the catalyst precursor film 23 to a catalyst film 24; and a plating step (S17) of forming the electroless plating film 26.

As shown in FIG. 2F, a wiring board 1 produced by the electroless plating method of the present embodiment includes a substrate 21, a patterned catalyst film 24 formed on the substrate 21, and a patterned electroless plating film 26 grown from the catalyst film 24.

### <Step S10> Solution Preparation Step

First, a catalyst solution is prepared. The catalyst solution contains: an organic compound of a first metal M1 that does not serve as a catalyst of an electroless plating reaction; an ion of a second metal M2 that serves as a catalyst of the electroless plating reaction; an organic compound that forms a complex with the first metal M1 and the second metal M2; and a photosensitive compound that does not form a complex with the first metal M1 and the second metal M2.

Hereinafter, the case where the first metal M1 is Ti and the second metal M2 is Cu will be described. Note that, as will be described below, the first metal M1 and the second metal M2 are not limited to these metals.

The catalyst solution containing the organic compound that forms a complex with the first metal M1 and the second metal M2 has high solubility of the first metal M1 and the second metal M2, and a solution having a predetermined concentration can be prepared. The use of an aromatic diol, particularly a derivative of an ortho-benzenediol in which a substituent is introduced into a carbon atom of a 4-position of the ortho-benzenediol, such as 4-ethyl protocatechuate (4-ethoxycarbonylcatechol: EtPCAT), as an organic compound that forms a complex with the first metal M1 and the second metal M2 preferably gives particularly high solubility to the catalyst solution of the first metal M1 and the second metal M2 to form a stable complex.

For example, EtPCAT forms a complex with Ti as shown below.

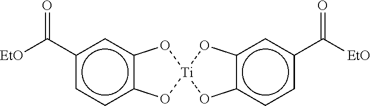

Next, a photosensitizer, in which the solubility in a predetermined solution largely changes when an active energy ray such as ultraviolet radiation is received, is used as a photosensitive compound (photo-active compound) that can be inhibited to form a complex with any of the first metal M1 and the second metal M2. Particularly, it is preferred to use a positive type photo-active compound bearing an acid generator moiety, which generates an acid when ultraviolet radiation is absorbed, on a ballast component in which alkali solubility is increased by the formation of the acid, for example, a naphthoquinonediazide esterification product.

A coating film of the TiCu catalyst solution in which the positive type photosensitive compound is not contained dissolves in an alkali developing solution used in the patterning step. On the other hand, a coating film to which a positive type photosensitive compound is added does not dissolve in the alkali developing solution but will dissolve in the alkali developing solution when ultraviolet rays are irradiated. That is, patterning of the coating film is achieved by the addition of the photosensitive compound.

As disclosed in Japanese Patent Application Laid-Open Publication No. 2011-207693, patterning of a Ti alkoxide film is achieved also when a photosensitive metal complex is used. However, in order to form a photosensitive metal complex, it is necessary to use a relatively expensive organic compound of a special structure. On the other hand, in the present embodiment, patterning is achieved only by adding a widely used positive type photosensitive compound to an alkoxide solution containing a catalytic metal.

In the electroless plating method of the present embodiment, a TiCu catalyst solution having a composition to be shown below has been prepared in which the first metal M1 is Ti and the second metal M2 is Cu.

### <TiCu Catalyst Solution>

| | |
|---|---|
| Titanium(IV) tetraisopropoxide: | 51.8 mL |
| Ti(OiPr)₄ | |
| Copper(II) acetate | 13.6 g |
| 4-Ethoxycarbonylcatechol | 77.4 g |
| (ethyl protocatechuate: EtPCAT) | |
| 2-Methoxyethoxyacetic acid | 10 mL |
| Ethyl lactate | proper amount |
| N,N-Dimethylacetamide (DMA) | 300 mL |
| Naphthoquinonediazide | 30 g (0.1 mol in terms of |
| esterification product A | a naphthoquinonediazide group) |
| Total | 1000 mL (adjusted with ethyl lactate) |

The TiCu catalyst solution contains an organic compound of Ti which is the first metal (titanium tetraisopropoxide), a compound of Cu which is the second metal serving as a catalyst of an electroless plating reaction (copper acetate), an organic compound that forms a complex with the first metal and the second metal (ethyl protocatechuate), and a photosensitive compound that does not form a complex with the first metal and the second metal (naphthoquinonediazide esterification product).

Examples of the titanium organic compound include titanium(IV) tetraisopropoxide, titanium(IV) tetrabutoxide, titanium(IV) tetraethoxide, and alkoxides including condensation products such as dimers, trimers, and tetramers of titanium(IV) tetraisopropoxide, titanium(IV) tetrabutoxide, and titanium(IV) tetraethoxide; chelates such as titanyl bis(acetylacetonate), dibutoxytitanium acetylacetonate, and diisopropoxytitanium triethanolaminate; and organic acid salts such as titanium stearate and titanium octylate. The organic compounds of titanium are liquid or solid at room temperature. Titanium alkoxides are preferred as the Ti organic compound.

Particularly preferred examples of the organic compound that forms a complex with the first metal M1 and the second metal M2 include EtPCAT, 2-methoxyethyl protocatechuate, benzyl protocatechuate, 3,4-dihydroxybenzonitrile, 4-methylcathecol, and 4-tert-butylcatechol.

Examples of the naphthoquinonediazide esterification product which is a positive type photosensitive compound include, but are not particularly limited to, an esterification product of naphthoquinone-1,2-diazide-5-sulfonyl chloride (NQD) and a polyphenol compound. Preferred examples of the polyphenol compound include 2,6-bis[2,5-dimethyl-3-(2-hydroxy-5-methylbenzyl)-4-hydroxybenzyl]-4-methylphenol (HMHM), 4,4′-dihydroxybenzophenone, 2,4′-dihydroxybenzophenone, 2,2′,4,4′-tetrahydroxybenzophenone, 2,4,4′-trihydroxybenzophenone, 2,3,3′,4,4′,5′-hexahydroxybenzophenone, 2,3,4-trihydroxybenzophenone, 2,3′,4,4′-tetrahydroxybenzophenone, tris(4-hydroxyphenyl)methane, bis(2,4-dihydroxyphenyl)methane, 2,4-bis[2-hydroxy-3-(4-hydroxybenzyl)-5-methylbenzyl]-6-cyclohexylphenol, 1-[1-(4-hydroxyphenyl)isopropyl]-4-[1,1-bis(4-hydroxyphenyl)ethyl]benzene, and dopamine (C₈H₁₁NO₂). The naphthoquinonediazide esterification product A is an esterification product of NQD and dopamine.

The esterification product can be produced, for example, by subjecting NQD and a polyphenol compound to condensation reaction followed by complete esterification or partial esterification. The condensation reaction is performed in the presence of a basic condensing agent such as triethylamine, an alkali carbonate, or an alkali hydrogencarbonate in an organic solvent such as dioxane, N-methyl pyrrolidone, chloroform, or dimethylacetamide.

The content of the positive type photosensitive compound in the catalyst solution is preferably 10 g/L or more and 60 g/L or less, particularly preferably 20 g/L or more and 50 g/L or less. When the content is equal to or more than the lower limit, the non-exposure area of the coating film will hardly dissolve in the alkali developing solution, but the exposure region will easily dissolve in the alkali developing solution. Therefore, high-precision patterning can be achieved. Further, when the content is equal to or less than the upper limit, the solubility of the exposure region in the alkali developing solution will not change, and the light exposure required for patterning will not largely increase.

Note that when the positive type photosensitive compound is a naphthoquinonediazide esterification product, the content of the naphthoquinonediazide esterification product is preferably 0.07 mol/L or more and 0.13 mol/L or less in terms of a naphthoquinonediazide group.

The TiCu catalyst solution in which the second metal M2 is copper contains copper acetate as a copper compound. A copper salt such as copper propionate and copper methoxyacetate may be used as a copper compound as long as the compound is a source of copper ions.

Note that the catalyst solution of the present embodiment further contains 2-methoxyethoxyacetic acid. The methoxyethoxyacetic acid is an organic solvent capable of dissolving metal ions that forms a complex with the second metal M2 in the catalyst solution to increase the solubility of the second metal M2 in the catalyst solution.

The amount of the methoxyethoxyacetic acid added to the catalyst solution is suitably set depending on the type and concentration of the second metal M2. For example, when the second metal M2 is copper and the concentration is 0.125 mol/L, the amount of the methoxyethoxyacetic acid added is preferably 5 mL/L or more and 20 mL/L or less. When the amount of the methoxyethoxyacetic acid added is equal to or more than the lower limit, the solubility of the second metal ion in the catalyst solution will be high, and when the amount of the methoxyethoxyacetic acid added is less than the lower limit, the second metal ion will not be completely dissolved or will precipitate in the coating liquid.

Note that methoxy acetic acid, methoxyethoxy ethoxy acetic acid, butyric acid, isobutyric acid, isovaleric acid, and the like may be used as a component capable of dissolving metal ions, instead of methoxyethoxyacetic acid or in addition to methoxyethoxyacetic acid.

### <Step S11> Coating Step

A substrate 21 was coated with the catalyst solution as shown in FIG. 2A. For example, a borosilicate glass (Tempax: manufactured by Schott AG: 50 [symbol] 50 [symbol] 0.7 mm in thickness) was coated with 0.35 mL of the catalyst solution by a spin coat method (1000 rpm) to form a coating film 22. The coating conditions are set depending on film thickness.

The substrate 21 may be an opaque ceramic substrate such as alumina as long as the substrate 21 has heat resistance that is equal to or higher than the heat treatment temperature in a curing step to be described below.

Drying treatment was performed at 120→C for 20 minutes. Since the boiling point of a solvent such as ethyl lactate is 150→C or more, some solvent may remain in the inner part of the coating film 22 even after the drying treatment, but the surface is solidified.

### <Step S12> Drying Step

The drying conditions may be, for example, at a temperature of 70→C or more and 110→C or less for 1 minute (inclusive) to about 10 minutes so that there may be no trouble in a patterning step.

### <Step S13> Patterning Step (Exposure Step)

As shown in FIG. 2B, the coating film 22 was pattern-wise exposed to ultraviolet radiation (UV) for 10 seconds through a photomask 31 with a mercury lamp (500 W Xe—Hg lamp: Ushio UXM-500SX) to form an exposure region 22A. In the pattern-wise exposure, a stepper or a pseudo-parallel-beam machine is preferably used for the purpose of high-precision patterning. For example, the exposure was performed through the photomask 31 in which L/S (unexposed region: line/exposure region: space) is 0.4 [symbol] m/0.4 [symbol] m. In the coating film 22 containing a positive type photosensitive compound, the exposure region 22A is changed to a region that is easily dissolvable in an alkali developing solution.

### <Step S14> Patterning Step (Developing Step)

As shown in FIG. 2C, when the exposed coating film 22 is developed by immersion treatment in an alkali developing solution for 30 seconds, the exposure region 22A was dissolved, and the coating film 22 was patterned.

Examples of the alkali developing solution include aqueous solutions of tetramethylammonium hydroxide (TMAH), sodium carbonate, potassium carbonate, ammonia, sodium hydroxide, potassium hydroxide, calcium hydroxide, monomethylamine, dimethylamine, trimethylamine, monoethylamine, diethylamine, triethylamine, monopropylamine, dimethylpropylamine, monoethanolamine, diethanolamine, triethanolamine, ethylenediamine, diethylenetriamine, dimethylaminoethyl methacrylate, polyethyleneimine, tetraethylammonium hydroxide (TEAH), tetrapropylammonium hydroxide (TPAH), and the like. The above materials may be used singly or in combination of two or more as an aqueous solution.

For example, aqueous solutions of 0.01 wt % to 0.1 wt % of TMAH, 0.1 wt % to 0.3 wt % of TEAR, and 0.5 wt % to 1.5 wt % of TPAH can be preferably used as an alkali developing solution.

The pH of the alkali developing solution is preferably in the range of 9 to 13. From the viewpoint of environmental loading reduction, the pH is more preferably in the range of 9 to 12.6, particularly preferably in the range of 9 to 12. The temperature of the alkali developing solution is adjusted according to the developability of a photosensitive layer. Further, a surfactant, a defoaming agent, an organic solvent, and the like may be added to the alkali developing solution.

Further, examples of the development processing include an immersion method, a spray method, brushing, and slapping.

Note that the steps until the patterning step (S10 to S14) is performed in a so-called yellow room where ultraviolet rays are intercepted.

### <Step S15> Curing Step

Curing treatment of the coating film 22 was performed. The curing treatment is, for example, a heat treatment at 400→C for 60 minutes which is performed in a heat treatment oven in the air. As shown in FIG. 2D, by the heat treatment, the coating film 22 is shrunk by curing to form a catalyst precursor film 23 having a thickness of about 1/10 of the thickness of the coating film 22.

Here, the curing is a reaction in which an organic compound of the first metal, titanium alkoxide in the present embodiment, is thermally decomposed to form a metal oxide (titanium oxide). The catalyst precursor film 23 has a structure in which second metal M2 ions are dispersed in an inorganic binder made of the first metal oxide M1Ox. Note that the coating film 22 containing Ti complexed with EtPCAT has a structure in which generally plate-like metal complexes are stacked in the thickness direction. Therefore, although the thickness will be 1/10 by the curing treatment, pattern width hardly changes.

The thickness of the catalyst precursor film 23 is preferably 10 nm or more and 150 nm or less, particularly 20 nm or more and 80 nm or less. When the thickness is equal to or more than the lower limit, an electroless plating film will stably form, and adhesion of the plating film will be good, and when the thickness is equal to or less than the upper limit, adhesion strength will not be reduced, and economic efficiency will be good.

Since the first metal oxide has a function as an inorganic binder, the catalyst precursor film 23 has high adhesiveness to the substrate 21.

The heat treatment conditions are, for example, 200→C or more and less than 500→C for 1 minute or more and 300 minutes or less in the air.

Note that the catalyst precursor film 23 is preferably a porous film having a large specific surface area. The catalyst precursor film 23 can be porous with a gas generated by solvent evaporation, decomposition reaction of the organic compound of the first metal, or the like.

### <Step S16> Reduction Step

The catalyst precursor film 23 was immersed for 2 minutes in an aqueous solution (50→C) containing 2 g/L of sodium borohydride (SBH) which is a reducing agent. As a reducing agent, hypophosphorous acid, hydrazine, boron hydride, dimethylamine borane, tetrahydroborate, and the like can be used.

By reduction treatment, the second metal M2 in an ionic state is reduced to metal particulate 25 having a catalyst function. On the other hand, the oxide of the first metal M1 is not reduced by the above reducing agent but remains as an oxide.

Therefore, as shown in FIG. 2E, the catalyst precursor film 23 will form a catalyst film 24 in the state where metal Cu particulates 25 having a catalyst function are dispersed in an inorganic oxide layer made of titanium oxide. That is, the catalyst film 24 is formed in which the particulates of the second metal serving as the catalyst of the electroless plating reaction are carried by the inorganic oxide layer of the first metal which does not serve as the catalyst of the electroless plating reaction.

Note that the porous catalyst precursor film 23 has a large specific surface area, and a large number of second metal ions are exposed to the surface. Since the large number of second metal ions are reduced to metal particulates 25, the catalyst film 24 produced from the porous catalyst precursor film 23 has high catalytic activity.

### <Step S17> Plating Step

As shown in FIG. 2F, when the substrate 21 on which the catalyst film 24 is formed is immersed in an electroless plating bath, an electroless plating film 26 made of a third metal M3 will be formed only on the patterned catalyst film 24. Various known compositions containing the third metal M3 ions and a reducing agent are used for the electroless plating bath. Note that the second metal M2 is particularly preferably the same catalyst as the third metal M3. For example, when a TiCu catalyst solution is used, a copper plating film is formed as the third metal M3 by using the metal particulate 25 made of copper of the second metal M2 as a catalyst. Cost reduction can be achieved by using inexpensive copper as the second metal that is a catalyst.

For example, by using an electroless plating bath A to be shown below, the electroless copper plating film 26 was formed using the catalyst film 24 in which the metal Cu particulates 25 were dispersed, and a wiring board 1 having the patterned electroless copper plating film 26 was produced.

### <Electroless Plating Bath A, Composition and Conditions>

Copper sulfate: 5 g/L

EDTA tetrasodium tetrahydrate: 55 g/L

PEG1000: 50 mg/L

2,2′-Dipyridyl: 10 mg/L

37% aqueous formaldehyde solution: 10 mL/L

Sodium hydroxide: adjusted to a pH of 12.5

Bath temperature: 60 to 70→C

Various known plating baths or commercially available baths may be used as the electroless copper plating bath.

Further, an electrolytic copper plating film having a thickness of 20 [symbol] m was formed using the electroless copper plating film as a base film in a known copper sulfate electroplating bath, followed by heat treatment at 350→C for 20 minutes (in a non-oxidizing atmosphere).

That is, the electroless plating method of the present invention may further include an electroplating step of forming an electroplating film using an electroless plating film as a base conductive film after the electroless plating step of forming an electroless plating film. The electroplating film preferably contains, as the main component, the same metal as in the electroless plating film.

### Evaluation

The thickness of the electroless plating film 26 was determined by producing a section sample and measuring the sample by TEM (transmission electron microscope). Further, L/S (line/space) was measured from a photograph by SEM (scanning electron microscope). Further, a sample that was not subjected to the patterning step was used to perform adhesive strength test (peel strength at 90-degree peeling, rate: 10 mm/min, 25→C) and cross-cut test (cut interval: 2 mm) of the plating film 26.

The thickness of the electroless plating film 26 formed on the catalyst film (thickness: 22 nm, L/S=2 [symbol] m/2 [symbol] m) was 0.2 [symbol] m, and L/S (line/space) was 2.4 [symbol] m/1.6 [symbol] m. Further, the number of grid patterns (cells) in which peeling occurred in the cross-cut test of the electroless copper plating film was 0/100, and the peel strength of the electrolytic copper plating film after heat treatment showed a practically sufficient strength of 0.25 kN/m.

That is, according to the electroless plating method of the embodiment, an electroless plating film 26 having fine patterning which has very high adhesive strength to a substrate 21 can be produced.

Note that the growth rate in the horizontal direction can be reduced compared with the growth rate in the perpendicular direction to perform so-called anisotropic growth by using, for example, pyridinium propylsulfonate, a derivative of pyridinium propylsulfonate, Janus green, Janus black, or 3,3′-dithiobis(1-propanesulfonic acid)disodium as an additive to the electroless copper plating bath. For example, an electroless copper plating bath to which 8 mg/L or more and 10 mg/L or less of Janus green is added shows a remarkable anisotropic growth effect by a higher growth rate in the perpendicular direction than the growth in the horizontal direction.

In the above description, an electroless plating method was described in which the first metal M1 is Ti and the second metal M2 and the third metal M3 are Cu.

However, Mg, Ca, Sr, Ba, Sc, Y, La—Lu, Ti, Zr, Hf, Nb, Ta, Mo, W, Zn, Al, Si, or Sn can be used as the first metal M1. A metal that is an electrochemically nobler metal than the first metal M1 and is reduced from ions to metal in the reduction step among Ru, Co, Rh, Ni, Pt, Cu, and Au can be used as the second metal M2.

Note that if Ag and Pd which are often used as an electroless plating catalyst are added to the catalyst solution as the second metal M2, photosensitivity may be lost probably because Ag and Pd decompose a photosensitive compound. Therefore, Ag and Pd cannot be used as the second metal M2.

Further, a metal such as Ru, Co, Rh, Ni, Pt, Cu, Ag, Pd, or Au, which can form a film by electroless plating, can be used as the third metal M3.

### Modification of the First Embodiment

Next, a modification of the electroless plating method will be described. In a modification of the electroless plating method, a catalyst solution contains a silane coupling agent.

The silane coupling agent is a compound having, in the molecule, a component such as an alkoxy silyl group that can react with a silica surface and polysulfide, a mercapto group, an epoxy group, or the like, or a compound that can be subjected to dehydration polymerization. Examples of the silane coupling agent which can be used include aminopropylsilane trialkoxide, dimethylaminopropylsilane trialkoxide, dialkylaminopropylsilane trialkoxide, dialkylaminopropylmethylsilane dialkoxide, dimethyloctadecylchlorosilane (ODS), an ethylene glycol-silane oligomer, or a silane oligomer subjected to dehydration polymerization.

The proportion of the silane coupling agent in the catalyst solution, for example, the amount of a compound obtained by reacting 1 mol of aminopropylmethylsilane diethoxide with 2 mol of glycidyl isopropyl ether (N,N-dialkylaminopropylmethylsilane dialkoxide) added is preferably 0.02 mol/L or more and 0.2 mol/L or less in terms of Si. If the proportion is higher than the upper limit, the catalytic activity will be reduced to prevent electroless plating from being deposited.

In a modification of the solution preparation step, a catalyst solution was prepared by adding 40 mL/L (0.09 mol/L in terms of Si) of the above dialkylaminopropylmethylsilane dialkoxide to the catalyst solution A before adjustment.

Then, a modification of the electroless copper plating film was formed from the coating film produced using the catalyst solution by the same steps as in the case of the electroless copper plating film 26.

With respect to a modification of the electroless plating film having a thickness of 0.3 [symbol] m formed on the catalyst film (thickness: 47 nm), the number of grid patterns (cells) in which peeling occurred was 0/100 in the cross-cut test, and the peel strength of the electrolytic copper plating film after heat treatment was 0.80 kN/m. That is, according to a modification of the electroless plating method, an electroless plating film having a higher adhesive strength than that in the electroless plating method of the embodiment can be obtained.

### Second Embodiment

An electroless plating method of the second embodiment and an electroless plating film of the second embodiment are similar to the electroless plating method of the first embodiment and the electroless plating film of the first embodiment, respectively. Therefore, only the points that differ from each other will be described.

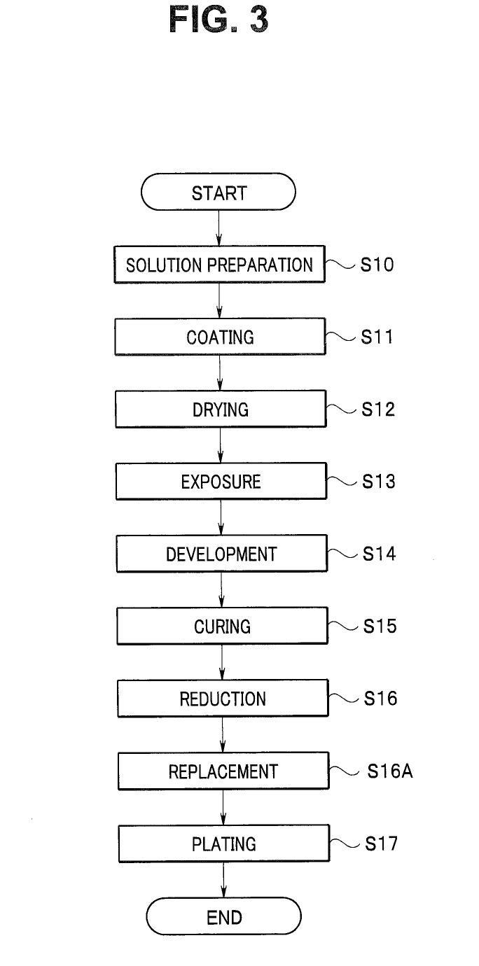

As shown in the flowchart of FIG. 3, the electroless plating method of the present embodiment further includes a replacement step S16A after the reduction step in addition to a plurality of steps of the electroless plating method of the first embodiment.

The metal copper of the catalyst film 24 of the first embodiment has a catalytic effect on the electroless copper plating bath. However, in order to form a catalyst film having higher activity, it is preferred to include a replacement step.

In the replacement step, the substrate on which the catalyst film is formed is immersed in a replacement aqueous solution containing ions of electrochemically nobler metals than Cu such as Pd ions, Ag ions, or Au ions.

The replacement aqueous solution containing Pd ions will be illustrated below,

| | |
|---|---|
| Pd chloride | 0.3 g/L |
| 35% HCl | 0.3 mL/L |

Replacement time is 10 seconds or more and 300 seconds or less, and the solution temperature is 25→C to 60→C.

Part of the metal copper of the catalyst film 24 is replaced by metal Pd in the replacement step by the above replacement solution containing Pd ions. Metal Pd is a catalyst having higher activity than metal Cu. Therefore, in the electroless plating method of the second embodiment, the copper plating film in the electroless copper plating step starts to precipitate earlier and more uniformly precipitates than in the electroless plating method of the first embodiment. Further, the catalyst film in which the metal copper particulates are replaced by Pd also act as a catalyst in the electroless plating bath of other metal than copper, for example, a Ni plating bath.

A replacement aqueous solution containing Au ions will be illustrated below.

Chloroauric acid 0.3 g/L

Replacement time is 10 seconds or more and 300 seconds or less, and the solution temperature is 60→C to 80→C.

Further, the catalyst film 24 containing the metal copper particulates of the first embodiment does not act as a catalyst in the electroless plating bath of a nobler metal than copper, for example, an Au plating bath. However, a catalyst film in which the metal copper particulates are replaced by Au which is nobler than Cu by replacement treatment acts as a catalyst also to Au or the like. Further, in the case of expensive metal such as Pd or Au, replacement of the inexpensive second metal M2 by the expensive metal in the replacement step is more economical than incorporating the expensive metal into the catalyst film 24 as the second metal M2.

For example, after the Pd or Au replacement step, an electroless gold plating film was formed using an electroless plating bath B to be shown below.

### <Electroless Plating Bath B, Composition and Conditions>

| | |
|---|---|
| Tiopronin-gold(I) tetramer | 3.6 g/L |
| Tripotassium citrate monohydrate | 15 g/L |
| Tripotassium phosphate | 15 g/L |
| N,N,N′,N′-ethylenediaminetetrakis | 5 g/L |
| (methylenephosphonic acid) | |
| 2-amino-5-mercapto-1,3,4-thiadiazole | 2.0 g/L |
| PEG1000 | 0.1 g/L |
| Ascorbic acid | 10 g/L |
| Bath temperature: | 75→C. |
| pH: | 6 (adjusted with |
| | sulfuric acid/KOH) |

Various known plating baths or commercially available baths may be used as the electroless gold plating bath.

The thickness of the electroless gold plating film formed on the catalyst film (thickness: 40 nm, L/S=1.8 [symbol] n/2.2 [symbol] m) was 0.3 [symbol] m, and L/S (line/space) was 2.0 [symbol] m/2.0 [symbol] m. Further, with respect to the electroless gold plating film, the number of grid patterns (cells) in which peeling occurred in the cross-cut test was 0/100, and the peel strength of the electrolytic copper plating film after heat treatment showed a practically sufficient strength of 0.25 kN/m.

That is, although an inexpensive metal is used as the second metal in the electroless plating method of the present embodiment, an electroless plating film can be produced which includes a metal such as Au that is nobler than the second metal and has high adhesive strength to a substrate.

Note that, also in the electroless plating method of the second embodiment, an electroless plating film having higher adhesive strength can be produced by using a catalyst solution to which a silane coupling agent is added, similar to the modification of the first embodiment.

The present invention is not limited to the embodiments and the like explained above. Various changes and modifications, for example, combinations of the components in the embodiments are possible without departing from the spirit of the invention.

What is claimed is:

1. An electroless plating method comprising:
a solution preparation step of preparing a catalyst solution containing titanium alkoxide, a copper ion, a derivative of an ortho-benzenediol in which a substituent is introduced into a carbon atom of a 4-position of the ortho-benzenediol, a naphthoquinonediazide esterification product, methoxyethoxyacetic acid, and a silane coupling agent;
a coating step of coating a substrate with the catalyst solution to form a coating film;
a patterning step of patterning the coating film by a photolithography method;
a curing step of converting the coating film to a catalyst precursor film, wherein the titanium alkoxide of the coating film is thermally decomposed to titanium oxide;
a reduction step of immersing the catalyst precursor film in a reducing agent-containing aqueous solution to reduce the copper ion to metal copper; and
a plating step of forming an electroless copper plating film.

2. An electroless plating method comprising:
a solution preparation step of preparing a catalyst solution containing an organic compound of a first metal that does not serve as a catalyst of an electroless plating reaction, an ion of a second metal that serves as a catalyst of the electroless plating reaction, an organic compound that forms a complex with the first metal and the second metal, and a photosensitive compound;
a coating step of coating a substrate with the catalyst solution to form a coating film;
a patterning step of patterning the coating film by a photolithography method;
a curing step of converting the coating film to a catalyst precursor film, wherein the organic compound of the first metal is thermally decomposed to a metal oxide;
a reduction step of immersing the catalyst precursor film in a reducing agent-containing aqueous solution to reduce the ion of the second metal to metal; and
a plating step of forming an electroless plating film of a third metal.

3. The electroless plating method according to claim 2, wherein the catalyst solution contains methoxyethoxyacetic acid.

4. The electroless plating method according to claim 2, wherein
the first metal is titanium;
the organic compound is titanium alkoxide;
the second metal is Ru, Co, Rh, Ni, Pt, Cu, In, or Au; and
the third metal is Ru, Co, Rh, Ni, Pt, Cu, Ag, In, Pd, or Au.

5. The electroless plating method according to claim 2, wherein the photosensitive compound is a naphthoquinonediazide esterification product which is a positive type photosensitive compound.

6. The electroless plating method according to claim 2, wherein the organic compound that forms a complex with the first metal and the second metal is at least any one of ethyl protocatechuate, 2-methoxyethyl protocatechuate, benzyl protocatechuate, 3,4-dihydroxybenzonitrile, 4-methylcathecol, and 4-tert-butylcatechol.

7. The electroless plating method according to claim 2, wherein the third metal is a same as the second metal.

8. The electroless plating method according to claim 2, wherein the second metal is Cu, and after the reduction step, the method further comprises a replacement step of immersing the substrate on which the second metal is formed in an aqueous solution containing a Pd ion, an Ag ion, or an Au ion.

9. A plating film formed by the electroless plating method according to claim 1.
